(19) United States
(12) Patent Application Publication
(10) Pub. No.: US 2017/0153452 A1
(43) Pub. Date: Jun. 1, 2017

(54) REFLECTING PLATE FOR DISPLAY, OPTICAL SYSTEM FOR PROJECTING DISPLAY LIGHT AND METHOD OF PRODUCING WINDSHIELD

(71) Applicant: YAZAKI CORPORATION, Tokyo (JP)

(72) Inventor: Junichi Matsushita, Shizuoka (JP)

(21) Appl. No.: 15/363,505

(22) Filed: Nov. 29, 2016

(30) Foreign Application Priority Data
Nov. 30, 2015 (JP) 2015-233572

(51) Int. Cl. G02B 27/01; C23C 14/34

(52) U.S. Cl. CPC G02B 27/0101; C23C 14/34

(57) ABSTRACT

A reflecting plate for display which is installed in a vehicle includes a first layer that is formed of a transparent first resin and has a first surface, and a second layer that is formed of a transparent second resin whose refractive index is the same as that of the first resin and is laminated on the first surface, wherein a predetermined region of the first surface functions as a half mirror which has a light transmission property and a light reflecting property.

### CROSS REFERENCE TO RELATED APPLICATIONS

This application claims a benefit of Japanese Patent Application (No. 2015-233572 filed on Nov. 30, 2015, the contents of which are incorporated herein by reference.

### BACKGROUND OF THE INVENTION

1. Technical Field

The present invention relates to a reflecting plate for display, an optical system for projecting display light and a method of producing a windshield.

2. Related Art

For example, in a typical vehicle head up display (HUD) device, an optical path is so formed that an image of light including various information that should be displayed is projected to a windshield (front window glass) or a reflecting plate, which is called a combiner, from an HUD unit, and the light that is reflected on the windshield is directed to the direction of the viewpoint of a driver. Therefore, it is possible for the driver to visually recognize the scenery ahead of the vehicle through the windshield, and visually recognize, as a virtual image, the HUD visual display information which is reflected on the windshield or the like at the same time. That is, while maintaining a normal driving state, the driver can visually recognize various information by the display of the HUD without moving eyes.

For example, in JP-A-2012-123393, special optical elements (equivalent to the combiner) are attached onto the glass surface of the windshield. The light that is emitted from the HUD unit is reflected on the surface of the optical elements on the windshield toward the viewpoint of the driver. Further, because the optical elements are made of a material through which visible light can transmit, it is possible for the driver to visually recognize images such as the scenery ahead of the vehicle as well as the display image that is imaged as a virtual image before the optical elements, which pass the windshield and the optical elements.

Further, in JP-A-2012-123393, a Fresnel lens is provided on the optical elements to form a magnifying optical system. Thereby, the HUD unit can be downsized. Because the Fresnel lens is used, the thickness of the optical elements can be reduced.

Further, for example, in JP-A-2014-008811, a technique to secure a good view of the rear side of the vehicle is shown. That is, a lens part is formed at a rear window made of resin, and the light that goes from the inside of the vehicle to the outside of the vehicle is deflected to the lower side of the rear window.

The display unit shown in t JP-A-2012-123393 is used while the Fresnel mirror is integrated with (or attached onto) the windshield or a combiner of the vehicle. However, to load the Fresnel mirror on the vehicle to obtain desired display properties, when the Fresnel mirror is attached to the windshield or the like, if the Fresnel mirror must be highly precisely arranged, and particularly a large-sized Fresnel mirror to obtain a wide field of vision angle is used, the attaching work is extremely difficult.

For example, because the windshield often has a complicated curved surface, if the position to attach deviates, the reflection direction of the display light deviates. Thereby, the region where a driver may visually recognize the display may become small. Further, in case that the shape of the Fresnel mirror does not correspond to the curved surface shape of the attaching surface of the windshield, during the attaching, the Fresnel mirror may flex and change in shape, and the optical properties also may change.

Further, when there is a gap between surfaces of the Fresnel mirror and the windshield, an unexpected reflection occurs, and the display quality decreases. That is, because while the display image which is reflected and imaged on the Fresnel mirror is expanded, the light that is reflected on a surface except the Fresnel mirror is imaged at the same size, an apparent difference occurs between the former display image and the latter image. Therefore, for example, when a display image of FIG. 5 A of JP-A-2012-123393 is displayed, a same-sized twin image ghost like FIG. 5B of JP-A-2012-123393 appears near the normal display image. Therefore, a drop of the visibility of the display image and a drop of the display quality are concerned.

Further, when the Fresnel mirror is attached to the windshield, heat may be applied and pressure may be applied. However, under the influence of the heat and pressure applied during the attaching, the Fresnel mirror deteriorates, and the optical properties may change.

The present invention is made in view of the above circumstances, and the object of the present invention is to provide a reflecting plate for display, an optical system for projecting display light, a windshield and a method of producing the windshield for which the operation of loading a Fresnel mirror on a vehicle is easy.

### SUMMARY

To achieve the previously described object, the reflecting plate for display, the optical system for projecting display light, the windshield and the method of producing the windshield of the present invention are characterized in the following (1) to (6).

(1) According to an aspect of the invention, a reflecting plate for display which is installed in a vehicle includes:
a first layer that is formed of a transparent first resin and has a first surface, and
a second layer that is formed of a transparent second resin whose refractive index is the same as that of the first resin and is laminated on the first surface,
wherein a predetermined region of the first surface functions as a half mirror which has a light transmission property and a light reflecting property.

According to the reflecting plate for display in the configuration (1), the display of HUD or the like is enabled by reflecting a predetermined display light at the half mirror. Further, because the first layer and the second layer of the reflecting plate for display are respectively formed of transparent resin, the reflecting plate for display can be formed integrally as an automotive resin windshield which is made, for example, by a molding process. By using the reflecting plate for display, loading onto the vehicle becomes extremely easy. Further, because the refractive index of the first resin and the refractive index of the second resin are almost the same, reflection and refraction of extra light at their borders can be prevented.

(2) In the reflecting plate for display of (1), the first surface in the predetermined region has a Fresnel shape.

According to this reflecting plate (2), because the first surface has a Fresnel shape, even if the thickness of material is not raised, it is possible to enlarge and project the reflected light by the surface of the half mirror.

(3) In the reflecting plate for display of (1) or (2), the predetermined region is located ahead of a driver's seat in the traveling direction of the vehicle.

According to this reflecting plate (3), an on-vehicle display system can be constructed so that, at a normal viewpoint position of the driver who is seated at the driver's seat, a virtual image of display light of HUD or the like can be visually recognized.

(4) In the reflecting plate for display of any one of (1) to (3), the first resin and the second resin construct a windshield.

According to this reflecting plate (4), because the reflecting plate for display is integrated with the windshield, a special attaching operation becomes unnecessary. That is, it is not necessary to perform operations such as exact aligning or attaching when the reflecting plate for display is loaded on the vehicle.

(5) According to another aspect of the invention, an optical system for projecting display light includes:
the reflecting plate for display according to any one of (1) to (4), and
a display unit that is loaded in a vehicle compartment and emits the display light.

In the optical system, the reflecting plate for display is installed in the vehicle so that the display light that is emitted from the display unit is reflected at the half minor, and an external light transmits through the half mirror and is incident into the vehicle compartment.

According to this optical system (5), the display light of the display unit is reflected at the half mirror and guided into a vehicle compartment, and a driver can visually recognize the display light as a virtual image. Further, because the driver can visually recognize external light transmitted through the half mirror together with the virtual image of the display light, this optical system for projecting display light can be used as an HUD system.

(6) According to another aspect of the invention, a method of producing a windshield includes:
forming a first layer that has a first surface with transparent resin;
forming a predetermined region of the first surface into a Fresnel shape;
forming a half mirror in the predetermined region of the first surface by vapor deposition or sputtering; and
laminating a second layer whose refractive index is the same as that of the first layer on the first layer and the half mirror.

According to this method (6), a transparent optical member having desired light reflecting property and light transmission property can be formed integrally in a step of producing the resin windshield. Therefore, a special operation to attach the optical member to the windshield on the vehicle becomes needless. Further, because the refractive index of the first layer and the refractive index of the second layer are almost the same, reflection and refraction of extra light at their borders can be prevented.

According to the reflecting plate for display, the optical system for projecting display light, the windshield and the method of producing the windshield of the present invention, it is not necessary to perform a special operation when the Fresnel mirror is loaded on a vehicle. Further, a Fresnel mirror of a large area and high precision can be realized relatively easily, even if the area of the part to reflect is small, by increasing the optical magnification of the Fresnel mirror, it is possible to raise the angle of the field of vision of a virtual image that the driver can visually recognize.

The present invention has been briefly described above. Further, details of the present invention will become more apparent after embodiments of the present invention described below (hereinafter referred to as “embodiments”) are read with reference to the accompanying figures.

### BRIEF DESCRIPTION OF DRAWINGS

FIG. 1 is a perspective view which indicates a constitution example of an area around a windshield and a dashboard of a vehicle on which an optical system for projecting display light of an embodiment the present invention is loaded.

FIG. 2 is a longitudinal sectional view which indicates that the vehicle and the optical system for projecting display light shown in FIG. 1 is watched laterally.

FIG. 3 is an optical path diagram which indicates an example of the constitution and the optical path of a Fresnel mirror forming part 10a included in a windshield 10.

FIGS. 4A to 4C represent a constitution example of a Fresnel lens included in the Fresnel mirror forming part 10a, in which FIG. 4A is a top view, FIG. 4B is a sectional view watched from the A-A line of FIG. 4A, and FIG. 4C is a sectional view watched from the B-B line of FIG. 4A.

FIG. 5A is a sectional view which indicates the constitution of the windshield of a variation, and FIG. 5B is a partly enlarged sectional view in which a part of FIG. 5A is enlarged and shown.

### DETAILED DESCRIPTION OF EMBODIMENTS

Specific embodiments of the present invention are described below with reference to the figures.

Specific embodiments related to the reflecting plate for display, the optical system for projecting display light and the method of producing a windshield of the present invention are described below with reference to the figures.

### <A Specific Example to Show an Environment Where the Optical System for Projecting Display Light is Used>

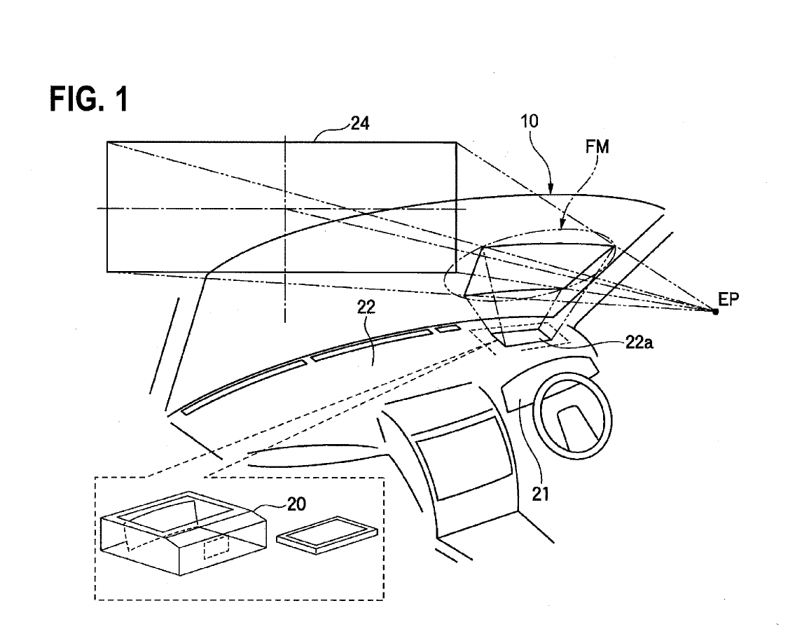

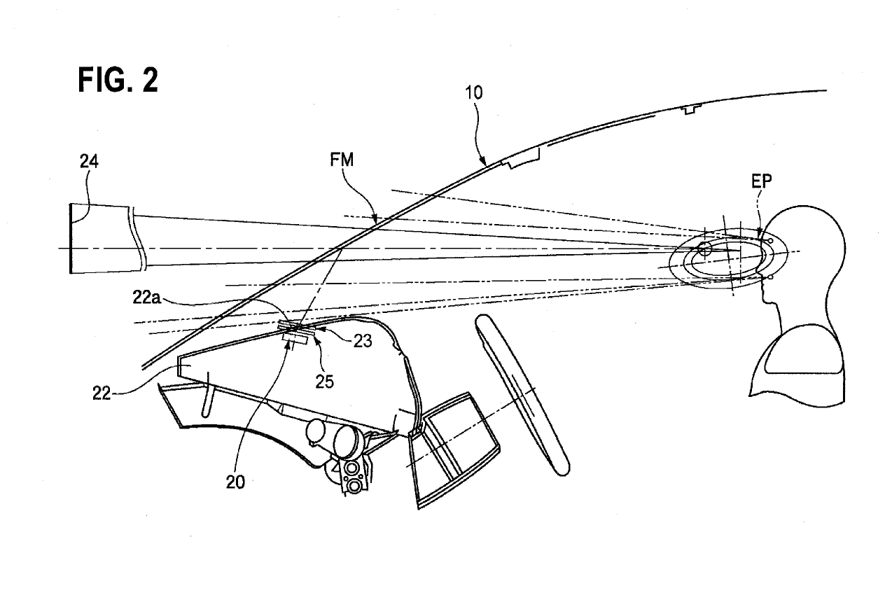

A constitution example of an area around a dashboard and a windshield 10 of a vehicle on which the optical system for projecting display light of the embodiment is loaded is shown in FIG. 1. Further, the arrangement of those parts in a longitudinal section in which the same vehicle as that in FIG. 1 is viewed laterally is shown in FIG. 2.

In the example shown in FIGS. 1 and 2, when the windshield 10 (window glass) of the vehicle is produced, the reflecting plate for display (Fresnel mirror forming part 10a to be described below) of the present invention is formed integrally. This reflecting plate for display forms a Fresnel mirror region FM on the windshield 10.

This Fresnel mirror region FM basically has the function of a half mirror, and has such a property that the light that is incident on the Fresnel mirror region FM from the inside of the vehicle compartment is mainly reflected and the light that is incident on the Fresnel mirror region FM toward the right direction in FIG. 2 from the outside of the vehicle compartment is mainly transmitted. Further, the Fresnel mirror region FM forms a magnifying optical system by a Fresnel lens. The specific constitution of the reflecting plate for display is described in detail later.

Although it is assumed in the example of FIGS. 1 and 2 that the reflecting plate for display of the present invention is integrated with the windshield 10 of the vehicle, the reflecting plate for display may be installed near the windshield 10, as a combiner for a HUD (head up display) device independent of the windshield 10.

In the vehicle shown in FIG. 1, an HUD unit 20 is arranged below a dashboard 22 in front of a meter unit 21. A flat panel display, which is formed of a transmissive liquid crystal panel and a polarizing plate, and a source of light (backlight) for illumination are built in this HUD unit 20. On the screen of the flat panel display, for example, various information that help driving such as vehicle speed is displayed as needed as visible information such as characters, numbers or signs. Further, by lighting up the screen with the backlight, the display light including the image of the displayed visible information can be emitted from the HUD unit 20.

A rectangular opening part 22a is formed at a place of the dashboard 22 above the HUD unit 20. The display light that is emitted from the HUD unit 20 propagates to the windshield 10 above via the opening part 22a. The above-mentioned Fresnel mirror region FM is arranged at a place of the windshield 10 where the display light from the HUD unit 20 is incident.

Therefore, the display light that is emitted from the HUD unit 20 is incident on the surface of the windshield 10, reflected in the Fresnel mirror region FM, and arrives at an eye point EP which corresponds to the position of the eyes of an assumed driver. Because this display light is reflected in the Fresnel mirror region FM, the display image which the driver visually recognizes is imaged as a virtual image as if it is displayed on a virtual image imaging surface 24 ahead of the windshield 10 (for example, 10 m ahead). Further, because the light that is incident from the front of the vehicle toward the inside of the vehicle compartment transmits through the Fresnel mirror region FM as well as the windshield 10, the driver can visually recognize the scene ahead of the vehicle through the Fresnel mirror region FM. That is, the scene ahead of the vehicle and the display image which the HUD unit 20 displays are overlapped and can be visually recognized at the same time.

By adopting the Fresnel mirror in the Fresnel mirror region FM, the thickness becomes small and it is possible to integrate with the windshield 10. Further, because the Fresnel mirror region FM forms a magnifying optical system, it is not necessary to have a magnifying optical system built in the HUD unit 20. Further, in comparison with a case to have a magnifying optical system built in the HUD unit 20, the opening area of the opening part 22a can be lowered.

Further, a louver 23 is arranged near the opening part 22a. This louver 23 has a function of preventing that unnecessary external light is reflected near the opening part 22a toward the eye point EP, and thereby improves the visibility of the HUD display.

<Description of the Fresnel Mirror Forming Part 10a>
<Constitution of the Fresnel Mirror Forming Part 10a>

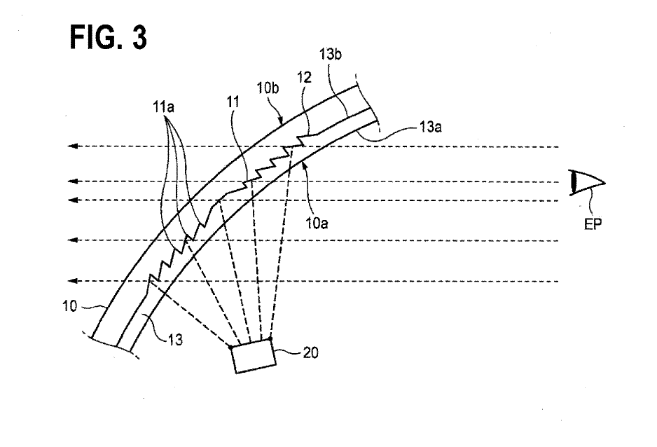

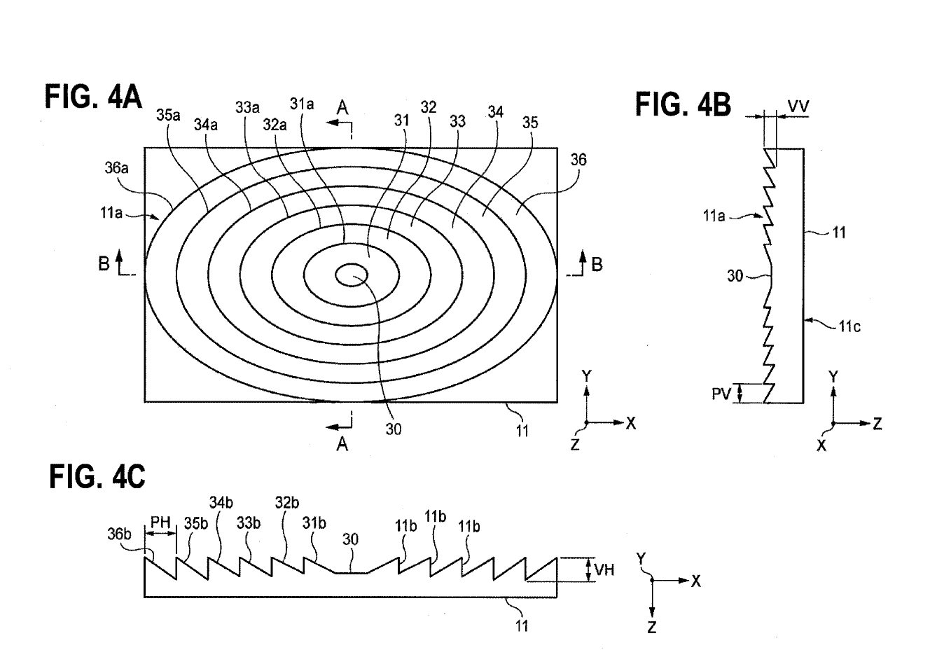

An example of the constitution and optical path of the Fresnel mirror forming part 10a included in the windshield 10, namely, the reflecting plate for display of the present invention is shown in FIG. 3. The Fresnel mirror forming part 10a shown in FIG. 3 is constructed as a combiner to reflect the display light of the HUD unit 20. This combiner is formed to have a rectangular shape like a Fresnel lens 11 shown in FIG. 4A, and have a size slightly larger than the Fresnel mirror region FM shown in FIG. 1.

As shown in FIG. 3, the Fresnel mirror forming part 10a is constructed of a plurality of layers that are laminated in the thickness direction. Specifically, the Fresnel mirror forming part 10a includes a half mirror layer 12 and a sealant layer 13 besides the Fresnel lens 11 as a substrate.

In this embodiment, the main body of the windshield 10 is not a general glass but is constructed of a board-like transparent main material 10b constructed by resin. The Fresnel lens 11 shown in FIG. 3 includes an irregular part of a Fresnel shape which is formed on the surface, at the inside of the vehicle compartment, of the transparent main material 10b of the windshield 10.

Further, on the surface of the Fresnel shape part 11a of this Fresnel lens 11, the half mirror layer 12 is formed. Specifically, a metal or dielectric multilayer film is deposited on the surface to form the half mirror layer 12. In this embodiment, the half mirror layer 12 is so constructed that the reflectivity of light in the half mirror layer 12 becomes 20%. The thickness of the formed half mirror layer 12 is assumed to be less than 100 [nm].

Further, when the half mirror layer 12 in the present embodiment is formed, the place of a Fresnel vertical wall 11b of the Fresnel shape part 11a is excluded from being a vapor deposition object. That is, the half mirror layer 12 is formed in the whole of the surface except the region of the Fresnel vertical walls 11b which extend in a direction parallel to the thickness direction at the borders of a plurality of ditches of the Fresnel shape part 11a. In this case, because there are not the half mirror layer 12 at the places of the Fresnel vertical walls 11b, a reflection on the Fresnel vertical walls 11b that takes an optical path except the normal transmission or single reflection is inhibited, and the outbreak of an unintended ray due to this reflection is minimized. Thereby, the outbreak of a flare image is also reduced.

The sealant layer 13 is provided to make a flat surface by covering the irregularity of the Fresnel shape part 11a of the Fresnel lens 11. This sealant layer 13 is formed by filling and stiffening, for example, transparent material such as ultraviolet ray (UV) hardening resin. Further, the material to form the sealant layer 13 is only limited to have a refractive index which is almost the same as that of the transparent main material 10b of the windshield 10 that constructs the Fresnel lens 11.

One surface 13a in the thickness direction of the sealant layer 13 is flat, and the other surface 13b that adheres to the Fresnel shape part 11a and the half mirror layer 12 is formed into a surface shape to supplement the irregularity of the Fresnel shape part 11a.

The Fresnel mirror forming part 10a shown in FIG. 3 is formed integrally with the windshield 10 in the example shown in FIGS. 1 and 2. That is, the half mirror layer 12 of the Fresnel mirror forming part 10a forms the Fresnel mirror region FM shown in FIGS. 1 and 2. The half mirror layer 12 forms a magnifying optical system for the light that is incident from the HUD unit 20, because an optical property that is equivalent to a general lens which has an optical magnification is formed by the shape of the Fresnel shape part 11a. Thereby, a virtual image can be imaged at a position (virtual image imaging surface 24) ahead of the windshield 10 with a distance.

In the example shown in FIGS. 1 and 2, the Fresnel mirror forming part 10a is integrated with the windshield 10, but an independent combiner may be arranged in a sloping state at a position different from the windshield 10, for example, on the dashboard 22.

### <Description of Transmission Property>

FIG. 3 shows the Fresnel mirror forming part 10a when the refractive index (n1) of the transparent main material 10b which is the material of the Fresnel lens 11 and the refractive index (n3) of the material of the sealant layer 13 are equal. When the Fresnel mirror forming part 10a is formed in this way, at the border between the Fresnel lens 11 and the sealant layer 13, the refraction of light due to a difference in refractive index can be inhibited.

When the refractive index is regulated in this way, even if an incident ray transmits the Fresnel mirror region FM, the scene ahead of the vehicle which the driver visually recognizes at the eye point EP shown in FIG. 2 is visually recognized as an image of the same size without an optical magnification. That is, when the scene ahead of the vehicle is visually recognized through the Fresnel mirror region FM, and when the scene is visually recognized through the region on the windshield 10 except the Fresnel mirror region FM, a difference will not produce in the size, position, shape or the like of the image of the visually recognized scene. Therefore, even when the Fresnel mirror region FM is used, a good view necessary for driving can be secured.

Further, by arranging the Fresnel mirror forming part 10a which has a magnifying optical system using the Fresnel lens 11 on the windshield 10, it is possible to display the virtual image of a wide field of vision angle with the HUD unit 20. Besides, because it is not necessary to equip with a magnifying optical system at the side of the HUD unit 20, downsizing of the HUD unit 20 is enabled and the area of the opening part 22a can be reduced.

### <A Constitution Example of the Fresnel Lens 11>

A constitution example of the Fresnel lens 11 included in the Fresnel mirror forming part 10a is shown in FIGS. 4A, 4B and 4C. FIG. 4A is a top view, FIG. 4B is a sectional view watched from the A-A line in FIG. 4A, and FIG. 4C is a sectional view watched from the B-B line in FIG. 4A. The Fresnel lens 11 constructing the substrate body is formed of materials such as transparent resin, glass or the like whose refractive index (n1) is known, into a sheet shape. Further, one surface in the thickness direction of the Fresnel lens 11 is formed with the Fresnel shape part 11a, and the other surface is a flat surface 11c.

It is described in this embodiment that, as shown in FIG. 4A, the outline and circumferences (31a, 32a, 33a, 34a, 35a, 36a) of the Fresnel lens 11 have a lot of oval or nearly oval Fresnel ditches 31, 32, 33, 34, 35 and 36, but even if the Fresnel ditches 31 to 36 are circular, by changing the inclination angle (sagged angle) of reflecting surfaces 31b to 36b to be described below in accordance with the difference in the circumferential positions of the ditches, distortion existing in the optical system can be inhibited.

It is necessary to increase or decrease the number or arrangement pitch of the Fresnel ditches in accordance with conditions such as required optical properties. These Fresnel ditches 31 to 36 are arranged concentrically around a central part 30 of the Fresnel lens 11.

As shown in FIGS. 4B and 4C, those parts between the Fresnel ditches 31 to 36 adjacent to each other project. That is, in the section, the Fresnel shape part 11a presents a serrated surface shape, and the reflecting surfaces 31b, 32b, 33b, 34b, 35b and 36b are formed as slopes which are inclined relative to a direction perpendicular to the thickness direction of the Fresnel lens 11. Further, at the borders of the reflecting surfaces of the Fresnel ditches adjacent to each other, there are the Fresnel vertical walls 11b extending in the thickness direction of the Fresnel lens 11, but the inclined reflecting surfaces 31b to 36b are formed almost continually so that it is not possible to be surfaces of a direction perpendicular to the thickness direction. By such a surface shape, a lens is formed optically.

In the Fresnel ditches 31 to 36, a free curved surface property is given to the optical reflection property of the Fresnel shape part 11a. Further, the inclination angles (sagged angles) of the reflecting surfaces 31b to 36b of the Fresnel ditches 31 to 36 are formed to change continually in accordance with the difference in the circumferential positions of the ditches.

When the ditch depth (VH, VV) of the Fresnel ditches 31 to 36 is constant, by continually changing the inclination angles of the reflecting surfaces 31b to 36b in accordance with the difference in the circumferential positions, the pitches (PH, PV) between the circumferences of the ditches adjacent to each other change in accordance with the circumferential positions and, as a result, the circumferential shapes of the Fresnel ditches 31 to 36 become a shape such as an oval.

In the example of FIGS. 4A, 4B and 4C, because of the oval pattern that the dimensions of the X-axis direction are bigger than the dimensions of the Y-axis direction, the pitch PV between the circumferences 35a and 36a in the A-A line section is smaller than the pitch PH between the circumferences 35a and 36a in the B-B line section. Further, the inclination angle of the reflecting surface 36b corresponding to the pitch PH is smaller than the inclination angle of the reflecting surface 36b corresponding to the pitch PV. Of course, an oval pattern whose dimension of the Y-axis direction is bigger than that of the X-axis direction may be obtained by the position where the Fresnel lens 11 is installed or the relative positional relationship with the eye point EP.

Further, when the depth (VH, VV) of the ditches is changeable in accordance with the change of the inclination angles (sagged angles) of the reflecting surfaces 31b to 36b, the pitch (PH, PV) between the circumferences of the ditches adjacent to each other can be constant. In this case, even if the shape of the Fresnel ditches 31 to 36 is a perfect circle or is almost a perfect circle, a free curved surface property can be given to the optical reflecting property.

Further, the circumferential outline shape of the Fresnel ditches 31 to 36 is not limited to the oval shape and the circular shape as shown in FIG. 4A, but, for example, a curved shape such as a contour line may be adopted in accordance with the required free curved surface property.

For example, when a distortion occurs so that in the display image imaged in the HUD display system, the vertical size of the image is different from the horizontal size of the image, by adopting the Fresnel lens 11 of the oval pattern whose aspect ratio is adjusted, the distortion of the image and binocular disparity are inhibited, and the display of high quality can be implemented. Besides, downsizing is possible because the Fresnel lens 11 is a thin, plate-like one.

As shown in FIGS. 4A, 4B and 4C, by forming the Fresnel shape part 11a of the Fresnel lens 11 into a special shape, a free curved surface property can be given to the optical reflection property, and an ideal polynomial aspherical lens property can be implemented. Thereby, even if a large-sized lens or mirror is not adopted, the imaging performance, binocular disparity, display distortion or the like in the HUD system are improved, and the display quality can be improved.

### <Method of Producing the Windshield 10>

When the windshield 10 with which the Fresnel mirror forming part 10a as shown in FIG. 3 is integrated is produced, the windshield 10 is produced with a procedure of (1) to (4) shown below.

(1) The substrate of the windshield 10 which is constructed with the transparent main material 10b whose refractive index is known is prepared. Further, it is desirable to adopt resin as the transparent main material 10b so that molding can be easy.

(2) On the surface, at the inside of the vehicle compartment, of this transparent main material 10b, at the place of the Fresnel mirror region FM, the irregularity of the Fresnel shape part 11a is formed, for example, as shown in FIGS. 4A, 4B and 4C, for example by a step of press-molding or a step of cut-machining.

(3) At some or the whole of the place where the Fresnel shape part 11a on the surface of the transparent main material 10b is formed, a metal or dielectric multilayer film is formed by a step of vapor deposition or sputtering. This film is the half mirror layer 12 and has a partial reflection function.

(4) The sealant layer 13 is formed by using transparent resin material to cover the surface of the region, where the half mirror layer 12 is given, of the Fresnel shape part 11a or the whole region of the Fresnel shape part 11a, and the Fresnel shape part 11a is sealed while the surface is smoothed. Further, as the material of the sealant layer 13, a material whose refractive index is equal to that of the transparent main material 10b is adopted. The sealant layer 13 is formed by a step of using UV hardening resin or a step of performing an in-molding of resin. Thereby, the sealant layer 13 is laminated at the place of the Fresnel shape part 11a and the half mirror layer 12.

### <Description of a Variation>

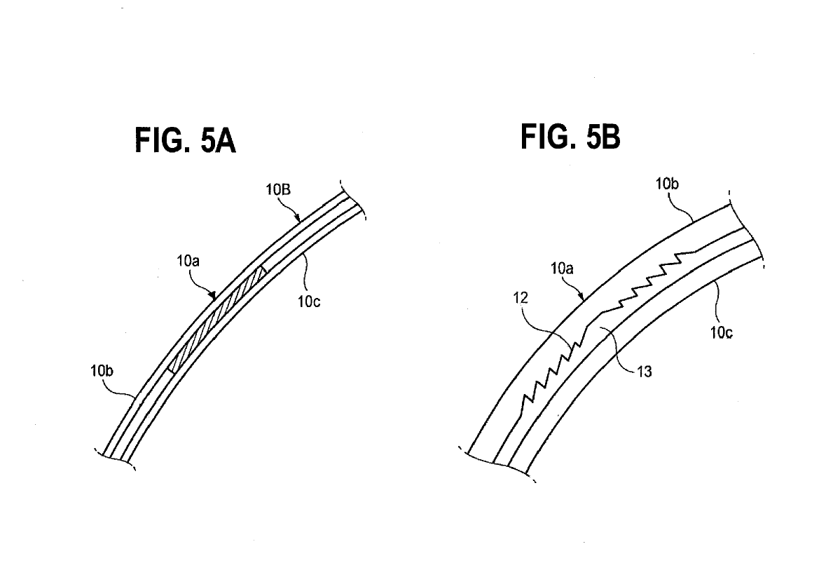

The constitution of a windshield 10B of the variation is shown in FIG. 5A. Further, the place of the Fresnel mirror forming part 10a in FIG. 5A is enlarged and shown in FIG. 5B.

The windshield 10B shown in FIGS. 5A and 5B is constructed as a laminated glass, and is so constructed that the above-mentioned Fresnel lens 11, the half mirror layer 12 and the sealant layer 13 formed in the Fresnel mirror forming part 10a are sandwiched between the outside transparent main material 10b and a transparent material 10c at the inside of the vehicle compartment.

Further, in the constitution shown in FIGS. 5A and 5B, the refractive index of the transparent material 10c becomes equal to that of the transparent main material 10b.

### <Advantage of the Windshield 10>

Because the Fresnel mirror forming part 10a shown in FIGS. 1 to 3 is formed by using the transparent main material 10b and the sealant layer 13 which are transparent resin materials, the processing is easy. Therefore, by a step of producing the windshield 10 as above, the windshield 10 including the Fresnel mirror forming part 10a can be formed integrally. That is, when the resin windshield produced by a molding process is loaded on a vehicle, only by adding the producing method described above to a part of this molding process, the windshield 10 including the Fresnel mirror forming part 10a can be produced.

When the windshield 10 is used, it is not necessary to attach a special reflecting plate to the windshield 10. Because the windshield typically has a complicated curved surface shape, when the reflecting plate is attached afterward, the influence of the change of a positional deviation or shape becomes easy to occur, and the operation becomes difficult. However, by forming the Fresnel mirror forming part 10a when the windshield 10 is produced, a highly precise positioning can be relatively easily implemented in accordance with the complicated curved surface shape.

Further, because the refractive index of the sealant layer 13 is equal to the refractive index of the transparent main material 10b, it can be prevented that unnecessary reflection or refraction occurs at these boundary surfaces, and a high quality HUD display is enabled. By providing such a property that sufficient optical magnification is obtained in the Fresnel mirror region FM, even when the area of the Fresnel mirror region FM is small, it is possible to raise the angle of field when a driver visually recognizes the HUD display.

Here, the features of the embodiments of the reflecting plate for display, the optical system for projecting display light and the method of producing a windshield according to the present invention described above are briefly, collectively listed in the following [1] to [6], respectively.

[1]0 A reflecting plate for display (Fresnel mirror forming part 10a) which is installed in a vehicle, including
a first layer (transparent main material 10b) which is formed of a transparent first resin and has a first surface, and
a second layer (sealant layer 13) which is formed of a transparent second resin whose refractive index is almost the same as that of the first resin and is laminated on the first surface, wherein
a predetermined region of the first surface functions as a half mirror (Fresnel mirror region FM) which has a light transmission property and a light reflecting property.

[2] The reflecting plate for display according to the above [1], wherein the first surface in the predetermined region has a Fresnel shape (Fresnel shape part 11a).

[3] The reflecting plate for display according to [1] or [2], wherein the predetermined region (Fresnel mirror region FM) is located ahead of a driver's seat in the traveling direction of the vehicle (refer to FIGS. 1 and 2)

[4] The reflecting plate for display according to either of the above [1] to [3], wherein the first resin and the second resin construct a windshield (10).

[5] An optical system for projecting display light, including the reflecting plate for display (Fresnel mirror forming part 10a) according to either of the above [1] to [4],and
a display unit (the HUD unit 20) which is loaded in a vehicle compartment and emits the display light, wherein
the reflecting plate for display is installed in the vehicle so that the display light that is emitted from the display unit is reflected at the half mirror (half mirror layer 12), and an external light transmits through the half mirror and is incident into the vehicle compartment.

[6] A method of producing a windshield, including forming a first layer (transparent main material 10b) which has a first surface with transparent resin,
forming a predetermined region of the first surface into a Fresnel shape (Fresnel shape part 11a),
forming a half mirror (half mirror layer 12) in the predetermined region of the first surface by vapor deposition or sputtering, and
laminating a second layer (sealant layer 13) whose refractive index is almost the same as that of the first layer on the first layer which includes the half mirror.

What is claimed is:

1. A reflecting plate for display which is installed in a vehicle comprising:
a first layer that is formed of a transparent first resin and has a first surface, and
a second layer that is formed of a transparent second resin whose refractive index is the same as that of the first resin and is laminated on the first surface,
wherein a predetermined region of the first surface functions as a half mirror which has a light transmission property and a light reflecting property.

2. The reflecting plate for display according to claim 1, wherein the first surface in the predetermined region has a Fresnel shape.

3. The reflecting plate for display according to claim 1, wherein the predetermined region is located ahead of a driver's seat in the traveling direction of the vehicle.

4. The reflecting plate for display according to claim 1, wherein the first resin and the second resin construct a windshield.

5. An optical system for projecting display light comprising:
the reflecting plate for display according to claim 1, and
a display unit that is loaded in a vehicle compartment and emits the display light,
wherein the reflecting plate for display is installed in the vehicle so that the display light that is emitted from the display unit is reflected at the half mirror, and an external light transmits through the half mirror and is incident into the vehicle compartment.

6. A method of producing a windshield, comprising:
forming a first layer that has a first surface with transparent resin;
forming a predetermined region of the first surface into a Fresnel shape;
forming a half mirror in the predetermined region of the first surface by vapor deposition or sputtering; and
laminating a second layer whose refractive index is the same as that of the first layer on the first layer and the half mirror.
